(19) United States
(12) Patent Application Publication
(10) Pub. No.: US 2022/0319829 A1
(43) Pub. Date: Oct. 6, 2022

(54) ASSEMBLIES USED FOR EMBEDDING INTEGRATED CIRCUIT ASSEMBLIES, AND THEIR USES AND METHOD OF FABRICATION THEREOF

(71) Applicant: Terecircuits Corporation, Mountain View, CA (US)

(72) Inventor: Jayna Sheats, Palo Alto, CA (US)

(21) Appl. No.: 17/657,247

(22) Filed: Mar. 30, 2022

Related U.S. Application Data
(60) Provisional application No. 63/169,658, filed on Apr. 1, 2021.

(51) Int. Cl. H01L 21/02; H01L 21/56; H01L 23/31; H01L 23/29

(52) U.S. Cl. CPC H01L 21/022; H01L 21/566; H01L 23/3192; H01L 23/29

(57) ABSTRACT

Assembly and laminates used for or in integrated circuit manufacturing are described, as well as the methods of fabrication and use. The assemblies may include closely spaced components held in place by a release layer or by vacuum applied to a porous substrate, and at least one embedding material deposited to encapsulate the components while leaving the side of the components comprising pads uncoated, thereby forming a laminate of the components and embedding material.

### INCORPORATION BY REFERENCE TO ANY PRIORITY APPLICATIONS

Any and all applications for which a foreign or domestic priority claim is identified in the Application Data Sheet or Request as filed with the present application are hereby incorporated by reference under 37 CFR 1.57, and Rules 4.18 and 20.6. U.S. Provisional App. No. 63/169,658, filed Apr. 1, 2021, is hereby incorporated by reference in its entirety.

### BACKGROUND

### Field

This invention is directed toward the formation of assemblies of microelectronic components.

### Description of the Related Art

Components such as packaged integrated circuits, capacitors, resistors and inductors are generally placed on printed circuit boards (“PCBs”), which have multiple layers of pre-formed wiring which terminates at landing pads which in turn are connected to the components by solder. Typically solder balls, or bumps, on the input/output (“I/O”) terminals of the integrated circuit (“IC”) packages are aligned and placed onto solder paste which has been printed on the PCB; the assembly is then passed through an oven called a reflow oven which melts the solder and allows it to form a joint. Passive components have relatively large metal-plated terminals which are similarly aligned and placed onto screen-printed solder paste patterns on the PCB.

This method has several shortcomings. The assembly must be heated to a temperature around 250-260° C. to melt the solder (e.g., a solder such as “SAC”, which has a common composition of 96.5% Sn, 3% Ag and 0.5% Cu) and subsequently allow it to flow freely over the pads, with temperature above 220° C. applied for a minute or longer. When the board cools, severe stresses tend to develop due to the very different coefficients of thermal expansion (CTE) of the different materials (e.g., the solder, polymers in the PCB, Cu, and Si in particular). The CTE of Si is 2.7 ppm/° C., Cu is 17 ppm/° C., SAC is about 23 ppm/° C., FR4 (which is a designation for a range of silica-filled epoxy composites used for PCB construction) is about 14-16 ppm/° C., and underfill polymers and/or varieties of epoxies are between about 15 and over 30 ppm/° C. near ambient temperature (above its glass transition temperature it may be substantially higher). These stresses may and often do lead to circuit failures due to breakage of solder joints, or delamination of the solder from the component (e.g., IC) pad. Further opportunities for failure arise during thermal cycling in use, for example in which the IC temperature may rise to 85° C. or more due to its operational heat generation.

As such, architectures and methods of manufacture that do not mitigate such shortcomings and failure points may be beneficial.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

In one aspect, an assembly used for integrated circuit manufacturing is disclosed. The assembly comprises: a substrate; a release layer disposed over the substrate; a plurality of components disposed over the release layer, wherein the plurality of components each comprise an active face in contact with the release layer; and an embedding material layer encapsulating the plurality of components.

In some embodiments, each of the active faces of the components do not substantially contact the embedding material. In some embodiments, the embedding material layer comprises a plurality of embedding material sublayers. In some embodiments, the embedding material layer comprises an amalgam. In some embodiments, the amalgam is a low CTE amalgam with a CTE of about −5 ppm/° C. to about 5 ppm/° C. In some embodiments, the amalgam comprises a matrix metal, an alloying metal and a low CTE material. In some embodiments, the matrix metal comprises Ga. In some embodiments, the alloying metal is selected from the group consisting of Cu, Ni, Ag, Ce, and combinations thereof. In some embodiments, the low CTE material is selected from the group consisting of ZrW₂O₈, HfW₂O₈, Sc₂W₃O₁₂, and combinations thereof. In some embodiments, the amalgam further comprises an element selected from the group consisting of an additional low CTE material, a passivating material, a liquid, a reducing agent, and combinations thereof. In some embodiments, the release layer comprises an undercut region positioned between the release layer and at least one component of the plurality of components. In some embodiments, the undercut region comprises a deposited material. In some embodiments, the substrate comprises pores.

In another aspect, a process of fabricating the assembly is described. The process comprises: depositing a plurality of components onto a release layer, wherein the release layer is disposed over a substrate; and encasing the plurality of components with an embedding material layer.

In some embodiments, encasing the plurality of components with the embedding material layer is performed by a spray process.

In another aspect, a process of integrating an assembly into an integrated circuit is described. The process comprises: separating a release layer from a plurality of components encapsulated by an embedding material layer of an assembly to form a laminate; and depositing an interconnect material over each exposed surface of the plurality of components to form a wired laminate.

In some embodiments, the process further comprises placing the wired laminate into a device, and electrically connecting the wired laminate to the device.

In another aspect, a laminate for integrating into a circuit device is described. The laminate comprises: a plurality of components each comprising a plurality of encapsulated surfaces and an exposed surface; and an embedding material encapsulating the plurality of encapsulated surfaces of the plurality of components.

In some embodiments, each of the exposed surfaces comprises a pad. In some embodiments, each of the exposed surfaces are substantially coplanar with each other. In some embodiments, the laminate further comprises interconnect materials disposed over each of the exposed surfaces. In some embodiments, the embedding material comprises an amalgam. In some embodiments, the amalgam comprises a matrix metal, an alloying metal and a low CTE material. In some embodiments, the amalgam is a low CTE amalgam with a CTE of about −5 ppm/° C. to about 5 ppm/° C.

### BRIEF DESCRIPTION OF THE DRAWINGS

These and other features, aspects, and advantages of the present disclosure are described with reference to the drawings of certain embodiments, which are intended to illustrate certain embodiments and not to limit the invention.

FIG. 1 is a line graph depicting the hardening kinetics for a gallium amalgam at various temperatures.

FIG. 2 is an illustration of a nebulizer system and method of use for spray deposition of an amalgam.

FIG. 3 is an illustration of a nebulizer that may be used for spray deposition of an amalgam.

FIG. 4 is an illustration of an assembly with an embedding material encapsulating components, according to some embodiments.

FIG. 5 is an illustration of an assembly with multiple embedding materials encapsulating components, according to some embodiments.

FIG. 6 is an illustration of an assembly with embedding material deposited in undercut regions beneath components, according to some embodiments.

FIG. 7 is an illustration of an assembly with embedding material deposited on components and a porous substrate with a vacuum applied to the porous substrate, according to some embodiments.

### DETAILED DESCRIPTION

Although certain embodiments and examples are described below, those of skill in the art will appreciate that the invention extends beyond the specifically disclosed embodiments and/or uses and obvious modifications and equivalents thereof. Thus, it is intended that the scope of the invention herein disclosed should not be limited by any particular embodiments described below.

Assemblies and laminates comprising components are provided, as well as their methods of use and fabrication. The assemblies may include closely spaced components held in place by a release layer or by vacuum applied to a porous substrate, and at least one embedding material deposited to encapsulate the components while leaving the side of the components comprising pads uncoated, thereby forming a laminate of the components and embedding material. Once the laminate is formed it may be separated from the substrate and release layer to be further processed, such as adding interconnects and/or integrated into a device. The embedding material may be selected to have favorable CTE, electrical insulating/conductive and/or thermally conductive properties. In addition, such assemblies may include a deposited material insulating one component from another.

The placement of components on a pre-wired PCB with landing pads sized for screen printing of solder is relatively difficult to print at resolutions of less than about 50 μm. Furthermore, using wiring, which is typically patterned from rolled Cu foil (e.g., at a thickness of 17 μm or 35 μm), in such a process typically results in separations of I/O terminals between components of at least a millimeter. Even if chip-scale packages (CSPs) are used, wherein the package is at most 1.3 times as large as the bare die, there is likely to be a distance of at least 1 mm from an I/O transistor terminal to the nearest component (e.g., a bypass capacitor). More commonly the distance between terminals of two ICs may be several centimeters. These separation distances between components are accompanied by resistive losses, as well as unwanted inductance near the IC.

Furthermore, the size of interconnects may be affected by the patterning technology used. The processes used for patterning Cu layers, which utilize relatively large aspect ratios where typically the traces are wider than they are high in order to achieve satisfactory geometry with isotropic wet etching, force interconnect traces to be many tens of μm wide (e.g., often at least 2 or 3 thousandths of an inch or more). Such interconnect limitations in turn increase the areal density, and the number of interconnect layers required.

Besides being laterally relatively large, the resulting structure is both thick and rigid (e.g., PCBs are typically about 1 mm thick, and packaged ICs are of the order of 0.5 mm thickness or more). Furthermore, heat dissipation through the IC package material and PCB is relatively poor due to the use of organic polymers with thermal conductivities of the order of 0.01% of that of Si.

Similar problems arise in the process for packaging integrated circuits. Conventionally, after singulation of a processed wafer a bare Si die is placed by a pick and place machine on a package substrate, which similar to a PCB may have pre-formed wiring to connect the I/O pads of the IC to the I/O pads of the package that are typically larger and spaced wider apart relative to the I/O pads of the IC. After forming the interconnects (e.g., by solder reflow, wirebonding, or another technique), the die and its substrate and wiring may be encapsulated in a protective polymer by injection molding. Many of the same issues, for example mismatch of material CTEs and extra length of interconnects, are also present in these processes.

In an attempt to solve some of these problems, some have utilized a reconstituted wafer where silicon dice from different source wafers are placed on a temporary substrate using a release layer type adhesive, and embedded in epoxy molding material in wafer format. Such a “reconstituted wafer” is then released from the substrate and further processed to add interconnects before forming the final packaged multi-die product. Several variations of this concept have been produced, including those by STATSChipPAC, Amkor, ASE and other companies. However, the epoxy package still results in substantial CTE mismatches, and the structures are susceptible to a large degree of warpage from these factors. Heat removal is also a problem. The packaged multi-die systems must still be placed on PCBs with other packaged ICs and components, with the same problems as have been described.

A desirable architecture would be one in which all of the ICs and other components needed by a circuit, regardless of their sizes, were placed as close together as possible (e.g., preferably with not more than a few μm between them) in bare form and surrounded on all but one surface (e.g., bottom surface) by a thermally conductive embedding medium or material whose CTE was similar to Si and whose surface was coplanar with the ICs. The ICs would be thin (e.g., less than 50 μm) which would make the product thin, and in some embodiments flexible. Such thinness may facilitate making a contiguous embedding or encapsulating layer as it is difficult to get solidifiable materials to flow uniformly into a space a few μm wide and 250 μm high. In addition, thinness minimizes the stress in the normal direction to the IC in part due to CTE mismatch of materials, and a thin but highly thermally conductive embedding medium allows for efficient heat removal.

With ICs placed within micrometers of each other, interconnect traces could advantageously be formed by fabricating them directly on the flat surface of the embedding medium, with approximately the same size as the final layer of interconnect within each IC. Two or more such ICs, or an IC with some relatively small passive components, will effectively act as one large IC. Such an architecture is difficult or impossible to fabricate utilizing lithography due to diminishing yields and the size limitations of the lithography equipment. Depending on the specific electrical requirements, the width and thickness of traces connecting two I/O pads that are not immediately adjacent may be greater than those that connect adjacent pads. However, such traces of the two I/O pads will likely still be relatively smaller than common PCB traces because of the smaller distance over which current is to be transported. For example, since the top layer interconnect in ICs is of the order of about 2 μm thick and 4-5 μm wide, these inter-component traces will be an order of magnitude or more smaller than in traditional technologies, which would allow for more compact routing and further savings in circuit area with improved electrical performance due to the shorter traces.

Once the required number of layers of interconnects (separated by dielectric layers) have been fabricated, the laminate may be encapsulated by one or more protective layers to make it ready for use in a product. These layers will typically be chosen according to specific requirements, and may be formed using materials well known in the art, such as metals (e.g. aluminum or copper), ceramics (e.g. oxides and nitrides), polyimides, polyester (such as poly(ethylene terephthalate), polyurethane, and others. Connections to other components, if needed, may be provided by metal traces which terminate at the edge of the substrate and are not covered by the final package, or through vias which may be formed through the protective encapsulation. Since complete functional circuits may be fabricated in one unit according to the invention, relatively small numbers of I/O connections are likely to be needed.

Such a structure can be used for any degree of integration, from circuits conventionally contained within single chips to those which currently occupy large PCBs. One application is to what are called “multi-die packages” or “system in package” devices, which may contain a few or even several IC dice in one package, but which is still intended to be placed on a conventional PCB along with others to form the final functional system. Another application is for relatively large and complex chips, such as high-end microprocessors, field-programmable gate arrays, and the like. These may be fabricated from “chiplets” that may not function alone as they are subunits of a functional IC and are combined appropriately to form a self-standing circuit. For example, such subunits could be the elements of a block diagram of a microprocessor (e.g., the core, the I/O section, the direct memory access (“DMA”) controller, the timing section, etc.). Advantages of such an architecture include the ability to easily upgrade a system with improvements in a specific subsystem without having to make completely new masks for the entire chip, the ability to quickly design a new system, and/or the ability to reduce power consumption and signal degradation due to long interconnect traces.

In some embodiments, an embedding material fluid is coated over a set of components disposed over a temporary release layer, wherein the fluid penetrates micron-scale gaps between the components and can be cured at low temperatures to a solid (e.g., flexible solid) embedding material and encapsulates the components. The fluid and solid compositions may be selected to have a thermal conductivity and CTE comparable or closely matched to silicon, and may be either electrically conductive or insulating.

Release layers and their methods of use are discussed in U.S. Pat. Nos. 6,946,178 and 7,141,348, which are incorporated herein by reference for all purposes. Triggering processes may be used for separating components from the release layer. As described in U.S. Pat. No. 6,946,178, the triggering processes include exposing the release layer to heat and light in a single step to degrade the release layer. Irradiation with light (e.g., actinic light) may be used to selectively activate a compound (e.g., polymer) of a release layer under a component which the user wishes to transfer, while leaving other components on the same substrate unactivated. Heating the compound of the release layer (also referred to as a digital release material (e.g., digital release adhesive (“DRA”))) to an appropriate temperature (e.g., less than about 150° C.) may cause the release layer to vaporize and release the component while leaving the unactivated devices still attached to the donor substrate. By this method, components may be held in place in close proximity by the release layer while an embedding material encapsulates the components on all sides except for the side facing the release layer, and subsequently the release layer may be decomposed to transfer the assembly and/or expose a non-encapsulated side of the components for application of interconnects. In some embodiments, transfer processes include Photopolymer Component Assembly (“PCA”) and Light-Induced Forward Transfer (“LIFT”).

In some embodiments, the embedding material comprises an amalgam mixture of gallium and particles of another metal (e.g., copper and/or nickel). Such amalgams may be fluid when first mixed, but as the elements interdiffuse a high melting point solid is formed. For example, the melting point of an alloy of about 65% Ga, 30% Cu, and 5% Ni melts at over 500° C., yet solidifies from a fluid mixture at ambient temperature (e.g., about 25° C. or about 30° C.). Such amalgams are described, for example, by U.S. Pat. No. 5,053,195 and in “Amalgams for Improved Electronics Interconnection”, IEEE Micro, pp. 46-58, 1993, each of which are incorporated by reference in their entirety for all purposes.

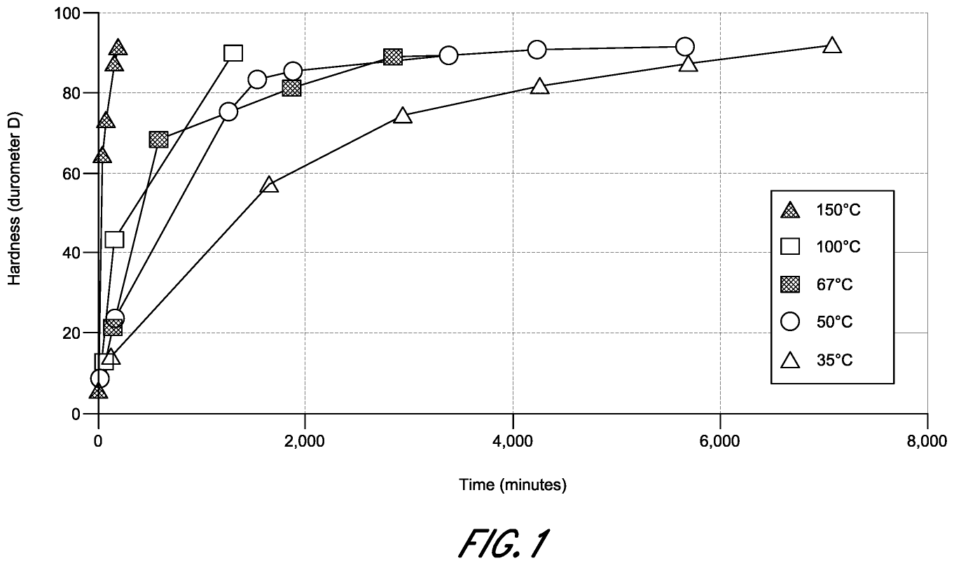

Some fluid amalgams may take several days for complete hardening to occur without heating. FIG. 1 depicts the hardening kinetics for a gallium amalgam (5% Ni, 30% Cu). However, such gallium amalgams with hardening results similar to those depicted in FIG. 1 have typically utilized powders with average particle diameters in the range of microns to tens of microns. Although evidence has been published (e.g., T. Okabe and R. J. Mitchell, in “Setting Reactions In Dental Amalgam Part 2. The Kinetics Of Amalgamation”, Critical Reviews of Oral and Biological Medicine, vol. 7, pp. 23-35) that there is relatively fast diffusion of liquid metal atoms along grain boundaries in amalgams, it has been demonstrated that smaller particles will lead to more homogeneous mixing (e.g., A. B. Shubin, et al. “The Diffusion of Gallium into Copper-Tin Alloy Particles”, Defect and Diffusion Forum Vols. 283-286 (2009) pp 238-242). Such smaller particles may not have been used because the mixtures tend to harden too quickly to be transferred from the mortar and pestle or amalgamator capsules in which these amalgam precursors were formed, and therefore are difficult to handle.

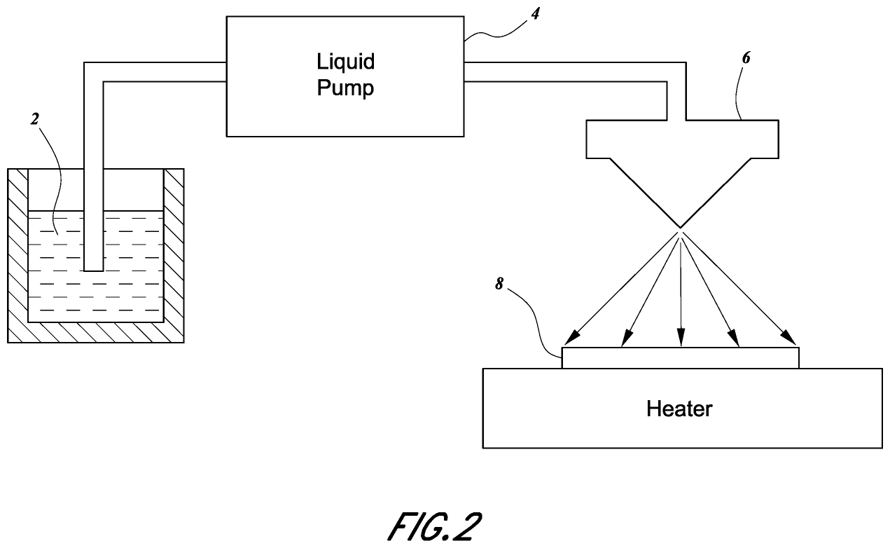

To avoid premature hardening and allow the use of submicron particles (e.g., nanoscale particles), in some embodiments the particles may be mixed in an ultrasonic mixer or jetting apparatus. In ultrasonic spray coaters (e.g., coaters made by Sono-tek Corporation, of Milton, N.Y.) liquid feedstocks are converted into aerosols by an ultrasonic atomizer immediately prior to coating. FIG. 2 depicts such a spray coating apparatus (i.e., nebulizer) for spray deposition as discussed in U.S. Pat. No. 6,358,567, which is incorporated by reference in its entirety for all purposes. The system includes liquid 2 pumped from a liquid pump 4 to an ultrasonic transducer 6 that is used to cause vibrations in the liquid to break up the sprayed liquid into small (e.g., sub-micron sized) droplets of an aerosol that are sprayed onto a substrate 8 disposed over a heater. There are a number of alternatives for making an aerosol spray of multiple particle types. In some embodiments, the liquid may comprise the metal particles present in a mixture (e.g., solution). For example, most metals (e.g., Cu and Ni) are not more reactive toward each other than they are toward themselves. Therefore, if the metal particles have been stabilized against agglomeration then the metal particles can be combined in a single solution or dispersion, and provided to the desired aerosol particle stream. In some embodiments, the liquid comprises a passivating material. In some embodiments, the metal particles comprise a passivating layer.

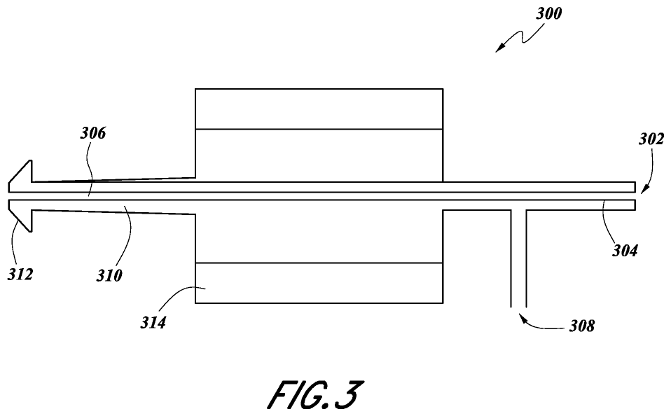

In some embodiments, different liquid streams may be combined as they enter the nebulizer, so as to minimize the amount of time during which the different particles are exposed to each other. FIG. 3 schematically depicts a commercial nebulizer 300 from the Sono-Tek Corporation, in which two input streams are combined. The nebulizer 300 includes a liquid A feed channel 302 that comprises a microbore tubing 304, and a liquid B feed channel 306 surrounding the liquid A feed channel 302 and the microbore tubing 304 and encased in a housing 314. At the distal end of the nebulizer 300, liquid A 306 and liquid B 310 are combined at an atomizing surface 312 and sprayed out of the nebulizer 300. In some embodiments, streams of gas may be used to direct streams of aerosol particles from separate liquid streams toward each other in order to mix them. Such shaping streams are used, for example by Sono-tek in some spray coating nozzles, and some aspects of shaping steams are disclosed in U.S. Pub. No. 2010/0078496, incorporated by reference in its entirety. Other jetting systems, such as those made by Optomec (Albuquerque, N. Mex.), nScrypt (Orlando, Fla.) or others may be used to form streams of nanoparticles for mixing and deposition. In some embodiments, the streams or liquids may include varying amounts of solvent. In some embodiments, the solvent may be a low-boiling solvent so that it is quickly evaporated once deposited from a surface. In some embodiments, the solvent may aid in producing a homogeneous, close-packed distribution of particles on the deposited surface. In some embodiments, where the velocity of droplets in such systems is of the order of a few, tens or hundreds of m/s (e.g., 1-900 m/s), the distance between dispenser tip and substrate is about a few millimeters and is traversed in at most a few milliseconds, therefore allowing relatively small metal particles to be used without hardening of the formed amalgam before deposition.

Metal (e.g., gallium) nanoparticles may be synthesized by a variety of methods. One example method for synthesizing gallium nanoparticles is described by M. F. Meléndrez, et al., in the Journal of Colloid and Interface Science, vol. 346, pp. 279-287 (2010), which is incorporated by reference in its entirety for all purposes. Since the melting point of Ga is about 29° C., the particles may be kept in solid form or delivered as a liquid. In some embodiments, Ga may be mixed with nanoparticulate metals by an ultrasonic nebulizer as described herein, which allow for deposition within milliseconds or less after mixing. In some embodiments, alternating thin layers of Ga and other nanoparticles may be deposited. In some embodiments, the resulting film of alternating thin layers of Ga and other nanoparticles is heated to melt the Ga and facilitate formation of a homogeneous distribution of particles in the fluid matrix, or with fluid occupying the interstices.

In some embodiments, metal nanoparticles are stabilized against agglomeration, since many bare metal surfaces are reactive and tend to stick to other similar surfaces. Examples of thin passivating coatings which can be removed at low temperatures are known and are commercially available. For example, a passivating coating for Cu is made by Zerovalent NanoMetals, in Rochester, N.Y., or the external surface of the metal particle may be oxidized to form a passivating coating. In some embodiments, reducing agents may be used to remove oxides formed on metal particle surfaces. In some embodiments, a forming gas (e.g., 4% H₂ in N₂, and/or formic acid) may be used in the gas stream of an application device (e.g., nebulizer) or applied in a separate stream to the deposition surface.

Although ultrasonic aerosol generators and their associated spray deposition are described, other methods of forming and depositing mixtures of nanoparticles may also be utilized. For example, suitable passivation of the particle surfaces may be achieved by oxide formation and/or the attachment of relatively labile organic ligands. In some embodiments, solutions or suspensions of the relatively unreactive particles may be mixed with a solution or suspension of Ga particles in an apparatus (e.g., a rapid-mixing apparatus), and then deposited by one of a variety of techniques (e.g., spray coating, slot die (i.e., meniscus) coating, and ultrasonic coating, and jetting under pressure (e.g., inkjet printing)). The protective passivation may be removed by heat, chemical treatment (e.g. forming gas, formic acid, etc.), and/or photolysis.

While FIG. 1 shows that a high-melting point solid can be formed without heating the object above ambient temperature (i.e., about 25° C.), it may be advantageous to heat the amalgam mixture (e.g., to about 85° C. or 100° C.) to complete the cure more rapidly. Such temperatures are often experienced by electronic products as a result of their normal operation, and so the circuit will likely see excursions to these values in any event. In some embodiments, the CTE of the amalgam is or is substantially matched to the circuit material (e.g., Si) to mitigate or prevent these excursions from causing damage relative to typical architectures.

In some embodiments, a low CTE amalgam is used. In some embodiments, the amalgam (e.g., low CTE amalgam) includes a matrix metal and an alloying metal. In some embodiments, the amalgam (e.g., low CTE amalgam) further includes a low CTE material. In some embodiments, the amalgam (e.g., low CTE amalgam) comprises an amount of the matrix metal of, of about, of at least, or of at least about, 40 wt. %, 45 wt. %, 50 wt. %, 55 wt. %, 60 wt. %, 65 wt. %, 70 wt. %, 75 wt. %, 80 wt. %, 85 wt. %, 90 wt. %, 92 wt. % or 95 wt. %, or any range of values therebetween. In some embodiments, the matrix metal comprises Ga. In some embodiments, the alloying metal is selected from Cu, Ni, Ag, Ce, and combinations thereof. In some embodiments, the low CTE material is selected from ZrW₂O₈, HfW₂O₈ and/or Sc₂W₃O₁₂. In some embodiments, the low CTE amalgam further includes an additional low CTE material. In some embodiments, the additional low CTE material is selected from SiO₂, Si₃N₄, Al₂O₃, Si, non-stoichiometric versions thereof, and combinations thereof. In some embodiments, the amalgam (e.g., low CTE amalgam) further includes a passivating material. In some embodiments, the amalgam (e.g., low CTE amalgam) further includes a liquid (e.g., solvent). In some embodiments, the liquid is a low viscosity liquid. In some embodiments, the amalgam (e.g., low CTE amalgam) further includes a reducing agent.

In some embodiments, the CTE of the amalgam (e.g., Ga amalgam) is about 15-20 ppm/° C., and may vary depending on the specific composition of the amalgam. In some embodiments, lower CTE values may be desirable. There are some materials whose CTE is very close to zero (i.e., smaller than Si), and in some cases even negative. For example, silica (SiO₂) has a CTE of about 0.5 ppm/° C. Thus, in some embodiments, a mixture of silica and amalgam in the appropriate proportions can lower the CTE closer to the desired value. Although the CTE of a mixture is not, in general, precisely equal to the mass-weighted average of the components, the relationship between mass fraction and CTE over a wide range of compositions is often close to linear or approximately linear. In some embodiments, the amalgam has a CTE of, or of about, −25 ppm/° C., −20 ppm/° C., −19 ppm/° C., −18 ppm/° C., −17 ppm/° C., −16 ppm/° C., −15 ppm/° C., −14 ppm/° C., −13 ppm/° C., −12 ppm/° C., −11 ppm/° C., −10 ppm/° C., −9 ppm/° C., −8 ppm/° C., −7 ppm/° C., −6 ppm/° C., −5 ppm/° C., −4 ppm/° C., −3 ppm/° C., −2 ppm/° C., −1 ppm/° C., −0.75 ppm/° C., −0.5 ppm/° C., −0.25 ppm/° C., −0.1 ppm/° C., 0 ppm/° C., 0.1 ppm/° C., 0.25 ppm/° C., 0.5 ppm/° C., 0.75 ppm/° C., 1 ppm/° C., 1.5 ppm/° C., 2 ppm/° C., 2.5 ppm/° C., 3 ppm/° C., 4 ppm/° C., 5 ppm/° C., 6 ppm/° C., 7 ppm/° C., 8 ppm/° C., 9 ppm/° C., 10 ppm/° C., 11 ppm/° C., 12 ppm/° C., 13 ppm/° C., 14 ppm/° C., 15 ppm/° C., 16 ppm/° C., 17 ppm/° C., 18 ppm/° C., 19 ppm/° C., 20 ppm/° C. or 25 ppm/° C., or any range of values therebetween.

One example of a negative CTE is provided by ZrW₂O₈, at about −7.2 ppm/° C. In order for the mixture of a material with negative CTE and positive CTE to have a net value between the two individual compounds' CTE's without experiencing undesirable stresses, the particles of the compounds should be as small as possible (e.g., nanoparticles). Nanoparticles of ZrW₂O₈ have been synthesized (see, for example, H. Wu, “Physical and Thermal Properties of Zirconium Tungstate Nanoparticles with Different Morphologies from Hydrothermal Synthesis”, MS thesis, Iowa State University, 2012; and “Optical and Dielectric studies in zirconium(IV) tungstate nanoparticles prepared by chemical co-precipitation method”, J. Iranian Chem. Res. 5 (2) (2012) 109-118).

In order to be useful as an embedding material layer for microcircuits, a composite amalgam material should preferably form a uniform solid at temperatures that is tolerated by the circuit components. ZrW₂O₈ is sintered at temperatures over 1000° C. and therefore may not be practical for use by itself, or in combination with other refractory materials. This problem has in fact prevented low or zero CTE materials from being used in many applications, as described by U.S. Pat. No. 6,132,676. However, by mixing the appropriate amount of ZrW₂O₈ into a Ga amalgam precursor, a uniform solid may be formed at low temperatures and pressures (e.g., atmospheric pressure and temperature less than 150° C. or less than 100° C.). Other compositional materials can be added in the same way, provided that the amalgam composition includes sufficient initially liquid Ga to fill the empty spaces between solid particles. The free volume in a uniform array of equally sized spherical particles is about 33% of the total, depending on the packing. However, by combining multimodal distributions, the free volume can be substantially reduced. For example, with three particle sizes, the remaining free volume may be about 4-5%.

The thermal conductivity of ZrW₂O₈, which is a ceramic material, is not as high as a typical metal or an elemental crystal such as silicon. According to C. A. Kennedy, et al., in Solid State Communications vol. 134, pp 271-276 (2005), it is about 1 W/m·K, as compared to 149 W/m·K for Si and 401 W/m·K for Cu. However, amalgams (e.g., Ga amalgams), depending on the specific composition, can have thermal conductivities well above that of matrix metal (e.g., Ga) alone, which is 40.6 W/m·K for Ga. With a 1:1 volume mixture of ZrW₂O₈ and Cu, compressed to 3 GPa and then heated to 500 C, X. Li, et al. were able to obtain a thermal conductivity of 165 W/m·K for a Ga amalgam (“High-pressure and high-temperature synthesis and study of the thermal properties of ZrW₂O₈/Cu composites”; Physica B: Physics of Condensed Matter, vol. 487, pp. 27-41 (2016)). Thus, using the more intimate interfacial contact available with the use of amalgams (e.g., Ga amalgams), it is possible to achieve both CTE and thermal conductivity close to that of silicon in a matrix. In some embodiments, the Ga amalgam comprises Ga-M and a negative CTE material (e.g., ZrW₂O₈), where “M” represents one or more metal atoms. In some embodiments, M is selected from Cu, Ni, Ag, Ce, and combinations thereof. In some embodiments, the negative CTE material is selected from ZrW₂O₈, HfW₂O₈ and/or Sc₂W₃O₁₂. In some embodiments, the Ga amalgam further comprises a low CTE material. In some embodiments, the low CTE material is selected from SiO₂, Si₃N₄, Al₂O₃, Si, non-stoichiometric versions thereof, and combinations thereof.

While matrix metals (e.g., Ga) generally form alloys with many other elements, the matrix metal may not mix with all other elements. For example, the solubility of Si in Ga is about 10⁻⁷ atomic %. In some embodiments, for the desired mechanical properties the interfaces between different microcrystallites should be as strong as possible. In some instances, alloys of matrix metals (e.g., Ga) may not form well-defined and strong bonds with oxides (e.g., ZrW₂O₈). However, nanoparticles may be made to be more compatible for forming alloys with each other by coating them using atomic layer deposition, which is a technique that is especially good for forming specific bonds between many metals and oxygen. In some embodiments, the matrix metal has a D50 average particle size of, of about, of at most, or of at most about, 5 nm, 10 nm, 15 nm, 20 nm, 25 nm, 30 nm, 35 nm, 40 nm, 50 nm, 60 nm, 70 nm, 80 nm, 100 nm, 150 nm, 200 nm, 250 nm, 300 nm, 400 nm, 500 nm, 600 nm, 700 nm, 800 nm, 900 nm or 1000 nm, or a particle size distribution defined by any range of values therebetween. In some embodiments, the alloying metal has a D50 average particle size of, of about, of at most, or of at most about, 5 nm, 10 nm, 15 nm, 20 nm, 25 nm, 30 nm, 35 nm, 40 nm, 50 nm, 60 nm, 70 nm, 80 nm, 100 nm, 150 nm, 200 nm, 250 nm, 300 nm, 400 nm, 500 nm, 600 nm, 700 nm, 800 nm, 900 nm or 1000 nm, or a particle size distribution defined by any range of values therebetween. In some embodiments, the low CTE material has a D50 average particle size of, of about, of at most, or of at most about, 5 nm, 10 nm, 15 nm, 20 nm, 25 nm, 30 nm, 35 nm, 40 nm, 50 nm, 60 nm, 70 nm, 80 nm, 100 nm, 150 nm, 200 nm, 250 nm, 300 nm, 400 nm, 500 nm, 600 nm, 700 nm, 800 nm, 900 nm or 1000 nm, or a particle size distribution defined by any range of values therebetween. In some embodiments, the additional low CTE material has a D50 average particle size of, of about, of at most, or of at most about, 5 nm, 10 nm, 15 nm, 20 nm, 25 nm, 30 nm, 35 nm, 40 nm, 50 nm, 60 nm, 70 nm, 80 nm, 100 nm, 150 nm, 200 nm, 250 nm, 300 nm, 400 nm, 500 nm, 600 nm, 700 nm, 800 nm, 900 nm or 1000 nm, or a particle size distribution defined by any range of values therebetween. In some embodiments, the amalgam includes multimodal particle size distributions of particles.

In some embodiments, thin pure metal layers can also be deposited by atomic layer deposition (“ALD”), with strong adhesion to substrates through bonds (e.g., chemical). In this way, metals can be bonded to the surface of a given type of nanoparticle which are more compatible with Ga alloys, so that stronger bonds may be subsequently formed. For example, Cu is a metal that has high compatibility with an ALD deposited Ga layer, but others are also known, including for example W, Pt, Co, Fe, Ag and Ni. Using fluidized bed technology (e.g., as practiced by ALD Nanosolutions in Broomfield, Colo.), these coatings can be put onto nanoparticles.

In some embodiments, the amalgam is electrically conducting, for example an amalgam in which a matrix metal (e.g., Ga) comprises the majority of the volume. In some embodiments, the amalgam is insulating, for example an amalgam in which a ceramic material (e.g., ZrW₂O₈) is the majority of the volume. In some embodiments, an advantage of an electrically conducting amalgam is that it can serve as the ground plane for an integrated circuit, eliminating the need for one layer in the interconnect portion of the circuit. In such an embodiment, the components could be electrically isolated from one another by depositing an insulating layer (e.g., of an insulating embedding material) before applying an embedding material comprising an electrically conductive amalgam composition. In some embodiments, the insulating layer may be a thin (e.g. at most about 1 μm) oxide layer, for example a layer of SiO₂. In some embodiments, the insulating layer is formed by plasma-enhanced chemical vapor deposition (PECVD) or any other deposition technique. In some embodiments, the insulating material and/or insulating amalgam material comprises a dielectric material selected from ZrW₂O₈, SiO₂, Al₂O₃, Si₃N₄, a polymer material (e.g., polyimide, liquid crystal polymers, and benzocyclobutene based polymer), non-stoichiometric ratios thereof, and combinations thereof.

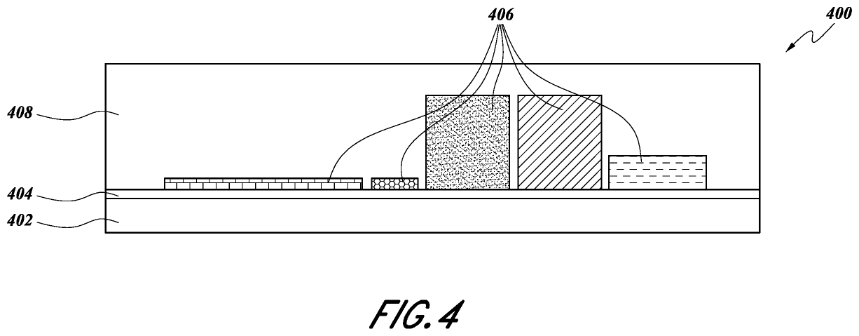

FIG. 4 illustrates an assembly 400 comprising a plurality of components 406 disposed over and held in place by a release layer 404 disposed over a temporary substrate 402, wherein the components 406 are encapsulated by a single layer of embedding material 408. In some embodiments, the embedding material 408 is an amalgam described herein. In some embodiments, the embedding material 408 is deposited to encase the components 406 by a method (e.g., spray deposition or multilayer deposition) described herein. Although it is to be understood that FIG. 4 is not drawn to scale, the relative height and width of the assembly 400 is intended to indicate that in some embodiments a large assembly aspect ratio that may be present. As depicted in FIG. 4, each component of the plurality of components may be of the same, similar and/or different height, width or shape as the other components. In some embodiments, the components may have a height of, of about, of at most, or of at most about, 2 μm, 3 μm, 5 μm, 8 μm, 10 μm, 15 μm, 20 μm, 25 μm, 30 μm, 35 μm, 40 μm, 45 μm, 50 μm, 60 μm, 70 μm, 80 μm, 90 μm, 100 μm, 150 μm, 200 μm, 300 μm, 400 μm, 500 μm, 600 μm, 700 μm, 800 μm or 1000 μm, or any range of values therebetween. For example, in some embodiments the thinnest components with regard to height may be of the order of 25 μm tall or thinner. In some embodiments, the spacing between two adjacent components is, is about, is at most, or is at most about, 0.1 μm, 0.5 μm, 1 μm, 2 μm, 3 μm, 4 μm, 5 μm, 6 μm, 7 μm, 8 μm, 9 μm, 10 μm, 12 μm, 15 μm or 20 μm, or any range of values therebetween. For example, in some embodiments the spacing between two adjacent components may be 5-10 μm or less. In some embodiments, the components may have a width of, of about, of at least, or of at least about, 3 μm, 4 μm, 5 μm, 6 μm, 7 μm, 8 μm, 9 μm, 10 μm, 12 μm, 15 μm, 20 μm, 25 μm, 30 μm, 35 μm, 40 μm, 45 μm, 50 μm, 60 μm, 70 μm, 80 μm, 90 μm, 100 μm, 150 μm, 200 μm, 300 μm, 400 μm, 500 μm, 600 μm, 700 μm, 800 μm, 900 μm, 1 mm, 2 mm, 3 mm, 4 mm or 5 mm, or any range of values therebetween. For example, in some embodiments the width of a component may be between about 25 μm and several mm. As illustrated, the components 406 are positioned upside down such that their active faces or sides (e.g., pads) are in contact with the release layer 404, and therefore the active sides are not in contact with the embedding material 408. In some embodiments, once the embedding material 408 is deposited it is hardened. In some embodiments, hardening is performed by heating and/or allowing the embedding material to cure while resting. In some embodiments, subsequent to deposition and/or hardening of the embedding material, the laminate comprising the components 406 and the embedding material is separated from the release layer 404 and substrate 402. In some embodiments, the laminate is peeled away from the release layer. In some embodiments, the release layer is decomposed (e.g., with light and/or heat) to separate the laminate from the substrate 402. In some embodiments, a component may be a passive component. In some embodiments, a passive component is a capacitor or resistor. In some embodiments, the components are about 150 μm tall (i.e., thick) or more. In some embodiments, the components about twice as wide as they are tall (i.e., thick). In some embodiments, microelectromechanical systems (“MEMS”) components, with primary packaging which protects the sensitive internal structures, may be of the order of 100 μm tall (e.g., thick) or more, and/or a few hundred to several hundred μm wide. In some embodiments, the embedding material is applied from an amalgam comprising a liquid. In some embodiments, the liquid is a low viscosity precursor liquid, which may allow complete filling of the narrow cracks between tall components with the embedding material. In some embodiments, the assembly further comprises a temporary border or dam that may be used to contain the amalgam at the edges of the assembly (e.g., while the material hardens). In some embodiments, the thickness of the release layer is, or is about, 0.5 μm, 1 μm, 2 μm, 3 μm, 4 μm, 5 μm, 6 μm, 7 μm, 8 μm, 9 μm, 10 μm, 12 μm, 15 μm, 20 μm or 25 μm, or any range of values therebetween. For example, in some embodiments the release layer is about 1-2 μm thick, which may be sufficient to hold the components on a flat surface. In some embodiments, the substrate surface has an average surface height variation of, of about, of at most, or of at most about, 0.01 μm, 0.05 μm, 0.1 μm, 0.5 μm, 1 μm, 2 μm, 3 μm, 4 μm or 5 μm, or any range of values therebetween.

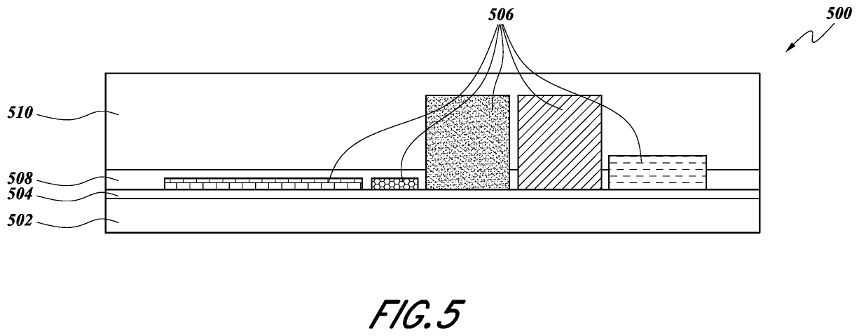

FIG. 5 illustrates an assembly 500 comprising a plurality of components 506 disposed over and held in place by a release layer 504 disposed over a temporary substrate 502, wherein the components 506 are encapsulated by a first layer of embedding material 508 and a second layer of an embedding material 510. In some embodiments, the first layer of embedding material 508 may comprise depressions and/or cracks, where the surface is only partially planarized by flow. In some embodiments, any number of embedding material layers may be used to encapsulate the components, such as, or at least, 1, 2, 3, 4, 5, 6, 7, 8, 9 or 10 layers, or any range of values therebetween. In some embodiments, a layer may comprise two or more sublayers of the same or different composition. In some embodiments, each of the embedding material layers may have the same, similar or different relative heights (i.e., thicknesses). In some embodiments, the embedding material of the first and/or second layer may include an insulating material, an amalgam material, or combinations thereof. In some embodiments, at least one of the embedding materials of the layers comprises an amalgam material. The elements of the assembly 500 of FIG. 5 and processes thereof may be similar to those described herein and with regard to FIG. 4.

In some embodiments, encapsulation of the components is performed after formation of the interconnects on the active side of the components. In some embodiments, encapsulation of the components is performed before formation of the interconnects on the active side of the components. In some embodiments, various compositions of embedding materials can be applied to encapsulate the components. In some embodiments, the first layer may be applied to the components first and allowed to become at least partially solidified. In some embodiments, the composition of the first layer may be selected to match as closely as possible the CTE of silicon, so that during thermal cycling the stress in and around the silicon ICs is as small as possible. In some embodiments, such a composition may increase the reliability of the contacts between metal interconnect lines and IC I/O pads. In some embodiments, the second layer with a second composition may subsequently be applied to the components over the first layer. In some embodiments, the second layer composition is selected for high thermal conductivity. In some embodiments, for example where at least some of the components rise above the height of the first layer, a modest mismatch of CTE of the first layer relative to the silicon may be tolerable. Such a modest mismatch of CTE may be acceptable, for example, where all the critical components in the first layer rise above and are not completely encapsulated by the first layer, and therefore the critical components will be approximately equally affected by the thermally induced expansions and contractions of the second layer. In some embodiments, wider or larger components, such as passive devices (e.g. resistors and ceramic capacitors) which are in contact with both the first and second layers, may be less affected by CTE mismatch because their larger contact areas provide more total adhered area to the interconnects and so are less susceptible to failure.

In some embodiments, two different embedding material compositions are used in two layers. In some embodiments, the two different embedding material compositions are configured to simultaneously optimize the thermal expansion match and the thermal conductivity of the device (e.g., circuit). In some embodiments, the thicknesses of each of the embedding material layers may be selected and configured for flexibility. In some embodiments, the multiple layers may have the same, similar, or different relative thicknesses. In some embodiments, the embedding material of the first layer may be an insulator material (e.g., insulating amalgam material), which as an example may eliminate the need for a dielectric layer. In some embodiments, the embedding material of the second or subsequent layer may a conductor, which as an example may form a ground plane and may in some instances contact some of the passive components, such as bypass capacitors which are all connected to ground.

In some embodiments, laminates and assemblies described herein may be suited for use with ultrathin components, or may be used with components which have not been thinned and may be much thicker. For example, components with thicknesses of or of about 250 μm or 500 μm may be utilized, which are examples of silicon wafer thicknesses that may appear in commercial products. Any component placement process may be used; for example the conventional pick and place processes disclosed in U.S. Pat. Nos. 6,946,178 and 7,141,348, which are incorporated by reference herein in their entirety for all purposes.

In some embodiments, one objective is to provide an embedding layer whose surface is coplanar with the component surfaces, for example as depicted in FIG. 4, so that high-resolution interconnects may be fabricated with minimal further processing of the surface. For example, one problem that arises with conventional injection molding embedding is that the components may be pushed into the temporary release layer, and then after application of the molding or embedding compound and release, a discontinuity in height between chip and embedding material, called mold flash, is present. This is described, for example, by U.S. Pat. No. 8,922,021, which is incorporated by reference in its entirety for all purposes. U.S. Pat. No. 8,922,021 describes ameliorating the problem by covering the surface with a layer of insulator and then forming vias to the I/O pads, which planarizes the surface but adds considerable expense and process complexity.

In some embodiments, the release layer (e.g., temporary adhesive polymer) has a thickness as described herein (e.g., about 1-2 μm). The release layer thickness may be configured such that it is sufficient to temporarily hold the components (e.g., typical surface mount components) as described herein to the substrate. In some embodiments, the substrate is or is substantially flat (i.e., low average surface height variation) as described herein (e.g., to within less than about ±1 μm variation). In some embodiments, and in contrast to some injection molding processes, the process by which the embedding material is applied does not involve strong lateral forces. In some embodiments, the components penetrate into the release layer (e.g., polymer film) by, by about, by at most, or by at most about, 1%, 5%, 10%, 20%, 30%, 40%, 50%, 60% or 70%, or any range of values therebetween, of the release layer thickness. In some embodiments, the resulting discontinuity of the release layer at the deposited component edge is, is about, is at most, or is at most about, 0.01 μm, 0.05 μm, 0.1 μm, 0.2 μm, 0.4 μm, 0.5 μm, 0.6 μm, 0.7 μm, 0.8 μm, 0.9 μm, 1 μm, 1.2 μm, 1.5 μm or 2 μm, or any range of values therebetween. In some embodiments, discontinuity of the release layer at the deposited component edge is comparable to topographic variations which are normally present on finished ICs. In some embodiments, assemblies and processes described herein may advantageously reduce the disturbing forces present during molding, and thereby reduce the requirement for thick release layers (e.g., temporary adhesive layers) into which extensive component penetration may occur.

In some embodiments, the release layer (e.g., temporary adhesive polymer) is a photoresist which loses a fraction of its mass as a consequence of light exposure and/or thermal development. In some embodiments, such photoresists are common in the microlithography industry and are based on the loss of t-butyoxycarbonyl moieties, whose loss may result in a loss of about 15% of the film thickness. In some embodiments, this decomposition results in gaseous products, and reduces (e.g., temporarily or permanently) the adhesion of any surface attached to the film. In some embodiments, the substrate and laminate comprising the components may be delaminated (e.g., pulled apart) as the decomposition takes place. In some embodiments, the decomposition of the release layer separates the substrate and laminate comprising the components.

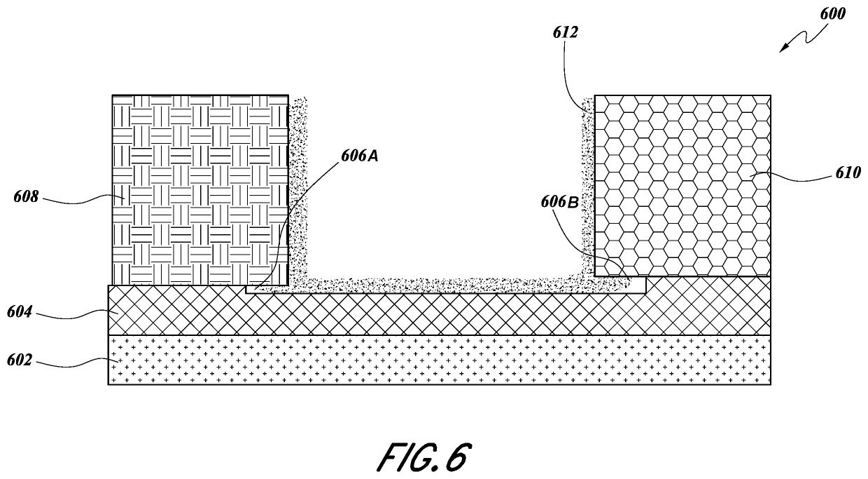

In some embodiments, the release layer material (e.g., photoresist polymer) may be etched (e.g., imaged and developed) to create small depressions between the component and the release layer. FIG. 6 illustrates an assembly 600 with a deposited material 612 deposited on the walls of and in undercut regions 606A and 606B of the release layer 604 beneath components 608 and 610, respectively. In some embodiments, the deposited material is an embedding material as described herein. In some embodiments, the deposited material is an insulating and/or dielectric material. The release layer 604 is disposed over a substrate 602, and the components 608 and 610 are disposed over the release layer 604. In some embodiments, the substrate 602 (e.g., temporary substrate) is a porous material. In some embodiments, the undercut regions 606A and 606B may be formed by optical exposure and/or thermal development of the material of the release layer 604 (e.g., polymer). In some embodiments, the distance the component overhangs the undercut region of the release layer (e.g., polymer) may be a few micrometers. In some embodiments, the distance the component overhangs the undercut region of the release layer (e.g., polymer) is, is about, is at most, or is at most about, 0.1 μm, 0.2 μm, 0.5 μm, 1 μm, 2 μm, 3 μm, 4 μm, 5 μm, 6 μm, 7 μm, 8 μm, 9 μm, 10 μm, 12 μm, 15 μm or 20 μm, or any range of values therebetween (e.g., about 2-10 μm). FIG. 6 depicts where the thickness of undercut region 606A is less than that of undercut region 606B, and where the thickness of the release layer 604 directly beneath component 608 is less that that beneath component 610. In some embodiments, the thickness of an undercut region and/or release layer region may be reduced relative to another undercut region and/or release layer region beneath two components due to one of the components positioned (e.g., depressed or having been pushed) more deeply into the release layer (e.g., polymer). In some embodiments, the depth of component depressions into the release layer is, is about, is at most, or is at most about, 25 nm, 50 nm, 75 nm, 100 nm, 125 nm, 150 nm, 200 nm, 250 nm, 300 nm, 400 nm, 500 nm, 600 nm, 800 nm or 1000 nm, or any range of values therebetween (e.g., about 150-300 nm, when the original release layer thickness film is about 1-2 μm; or when the original release layer thickness film is about 2-10 μm relatively deeper depression is formed). In some embodiments, the release layer is irradiated with light prior to disposing the components over the release layer and undercut regions. In some embodiments, irradiation of the release layer forms a sensitized release layer. In some embodiments, the sensitized release layer decomposes when sufficient heat is applied. In some embodiments, the release layer is deposited on the substrate as a sensitized release layer. In some embodiments, the release layer is irradiated with light subsequent to disposing the components over the release layer and undercut regions. In some embodiments, once the components are disposed over the release layer and undercut regions, the deposited material (e.g., dielectric film) is then deposited on the walls of the components and within the undercut regions. In some embodiments, deposition of the deposited material is performed by sputtering or PECVD. In some embodiments, the mean free path of the reactive molecules of the deposited material is sufficiently small that at least some of them diffuse under the overhang before depositing, resulting in a thin layer with tapered thickness further into the undercut regions as shown in FIG. 4.

In some embodiments the deposited material makes a smooth transition across the edge of the component. In some embodiments, the deposited material covers the edges of components, whose sharpness might otherwise make it difficult to fabricate interconnects later. In some embodiments, the deposited material insulates the components (e.g., chips) from later deposited interconnects, and for example may insulate regardless of what metal structures might be part of an IC close to its edge. In some embodiments, this smooth transition of the deposited material may compensate for any difference in height which might be present due to different amounts of penetration of the components within the release layer (e.g., polymer). In some embodiments, the assembly 600 may be further processed to encase the components 608 and 610 with embedding materials and/or release the components from the release layer 604 and substrate 602. In some embodiments, after deposited material (e.g., dielectric) deposition the release layer (e.g., photoresist film) is heated to cause the release material (e.g., t-butyoxycarbonyl) decomposition and reduction in adhesion. In some embodiments, when the deposited material is a dielectric, a thicker graded deposit will be formed that may be useful for covering some edge defects or structures of components.

In some embodiments, the release layer is a thermally decomposable polymer such as disclosed in U.S. Pat. Nos. 7,300,824 and 7,863,762, which are incorporated by reference in their entirety for all purposes. In some embodiments, the release layer (e.g., polymer film with or without photosensitizer) may be formed on a porous substrate that can serve as a porous vacuum chuck. In some embodiments, for example after all of the components for a circuit have been placed on the release layer and at least the deposited material (e.g., dielectric layer) is deposited, the release layer is heated to a decomposition temperature while a vacuum is applied to the porous vacuum chuck, thereby causing the decomposition products of the release layer to exit through the pores of the porous vacuum chuck while the porous vacuum chuck holds the component laminate in place. In some embodiments, the embedding material may be applied prior to or subsequent to decomposition of the release layer.

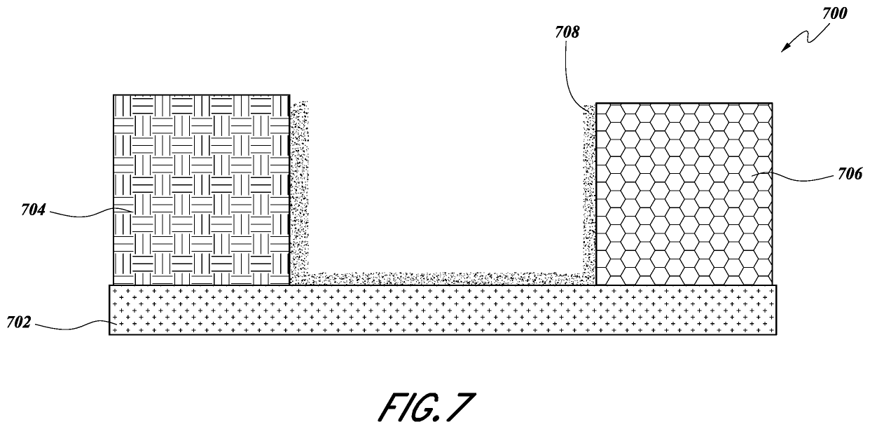

In some embodiments, the release layer may be decomposed before the deposition of the release material (e.g., dielectric). In some embodiments, the vacuum from the porous vacuum chuck holds the individual components in place, even when there are undercut regions, because this area is a small fraction of the total area, and an adequate pressure differential may be maintained across the components in spite of the open area. In some embodiments, the deposited material (e.g., dielectric film) is then deposited using an atmospheric pressure process (e.g., atmospheric pressure PECVD). In some embodiments, the surfaces of the components are directly in contact with the surface of the substrate (e.g., porous vacuum chuck). In some embodiments, the porous vacuum chuck defines a, or a substantially, flat, planar surface regardless of any difference in the extent to which components had penetrated into the release layer (e.g., polymer). Such an assembly 700 structure is illustrated in FIG. 7. FIG. 7 illustrates the components 704 and 706 disposed over the substrate 702 (e.g., temporary substrate) after removal of a release layer (e.g., temporary adhesive layer) and deposition of a deposited material (e.g., insulating dielectric). In some embodiments, the insulating material is deposited prior to or subsequent to removal of the release layer (e.g., adhesive). In some embodiments, the contact (e.g., adhesion) between the deposited material (e.g., dielectric film) and the substrate 702 may be separated (e.g., broken) when the component laminate (e.g., circuit laminate) is peeled away, as it comprises only a small fraction of the total area. In some embodiments, to facilitate the separation of components from the substrate, the substrate may be treated with a low surface energy coating (e.g., thin coating). In some embodiments, the low surface energy coating is selected from a plasma-deposited fluorocarbon film, self-assembled monolayer of fluorocarbons, or combinations thereof. In some embodiments, the assembly 700 may be further processed to encase the components 704 and 706 with embedding materials and/or release the components from the substrate 702. In some embodiments, the separated component laminate may be further processed to add interconnects to the active faces of the components.

In some embodiments, the porous vacuum chuck comprises a plurality of pores. In some embodiments, the pores are of nanometer-scale diameters and/or micron-scale diameters. In some embodiments, the pores have an average diameter of, of about, of at most, or of at most about, 5 nm, 10 nm, 20 nm, 30 nm, 40 nm, 50 nm, 75 nm, 100 nm, 150 nm, 200 nm, 300 nm, 400 nm, 500 nm, 600 nm, 800 nm, 1 μm, 1.5 μm, 2 μm, 3 μm, 5 μm or 10 μm, or any range of values therebetween. In some embodiments, the substrate (e.g., porous vacuum chuck) comprises silicon.

In some embodiments, the release layer is deposited on the porous vacuum chuck prior to component deposition. In some embodiments, a vacuum chuck may not be used to hold the components during the component placement process because, for example, initially all of the area is exposed and the first components placed would not be subject to sufficient holding force. In some embodiments, vacuum can be applied once the release layer and components are placed on the substrate, and the vacuum is sufficient to hold the components due to the reduction of exposed area on the porous vacuum chuck prior to or subsequent to decomposition of the release layer (e.g., temporary adhesive) (e.g., exposed spaces in between the closely-spaced components).

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products. For example, any of the components for an energy storage system described herein can be provided separately, or integrated together (e.g., packaged together, or attached together) to form an energy storage system.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount, depending on the desired function or desired result.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

The headings provided herein, if any, are for convenience only and do not necessarily affect the scope or meaning of the devices and methods disclosed herein.

What is claimed is:

1. An assembly used for integrated circuit manufacturing, comprising:
a substrate;
a release layer disposed over the substrate;
a plurality of components disposed over the release layer, wherein the plurality of components each comprise an active face in contact with the release layer; and
an embedding material layer encapsulating the plurality of components.

2. The assembly of claim 1, wherein each of the active faces of the components do not substantially contact the embedding material.

3. The assembly of claim 1, wherein the embedding material layer comprises a plurality of embedding material sublayers.

4. The assembly of claim 1, wherein the embedding material layer comprises an amalgam.

5. The assembly of claim 4, wherein the amalgam is a low CTE amalgam with a CTE of about −5 ppm/° C. to about 5 ppm/° C.

6. The assembly of claim 4, wherein the amalgam comprises a matrix metal, an alloying metal and a low CTE material.

7. The assembly of claim 6, wherein the matrix metal comprises Ga.

8. The assembly of claim 6, wherein the alloying metal is selected from the group consisting of Cu, Ni, Ag, Ce, and combinations thereof.

9. The assembly of claim 6, wherein the low CTE material is selected from the group consisting of ZrW₂O₈, HfW₂O₈, Sc₂W₃O₁₂, and combinations thereof.

10. The assembly of claim 4, wherein the amalgam further comprises an element selected from the group consisting of an additional low CTE material, a passivating material, a liquid, a reducing agent, and combinations thereof.

11. The assembly of claim 1, wherein the release layer comprises an undercut region positioned between the release layer and at least one component of the plurality of components.

12. The assembly of claim 11, wherein the undercut region comprises a deposited material.

13. The assembly of claim 1, wherein the substrate comprises pores.

14. A process of fabricating the assembly of claim 1, comprising:
depositing the plurality of components onto the release layer, wherein the release layer is disposed over the substrate; and
encasing the plurality of components with the embedding material layer.

15. The process of claim 14, wherein encasing the plurality of components with the embedding material layer is performed by a spray process.

16. A process of integrating an assembly into an integrated circuit, comprising:
separating the release layer from the plurality of components encapsulated by the embedding material layer of the assembly of claim 1 to form a laminate; and
depositing an interconnect material over each of the exposed surfaces of the plurality of components to form a wired laminate.

17. The process of claim 16, further comprising placing the wired laminate into a device, and electrically connecting the wired laminate to the device.

18. A laminate for integrating into a circuit device, comprising:
a plurality of components each comprising a plurality of encapsulated surfaces and an exposed surface; and
an embedding material encapsulating the plurality of encapsulated surfaces of the plurality of components.

19. The laminate of claim 18, wherein each of the exposed surfaces comprises a pad.

20. The laminate of claim 18, wherein each of the exposed surfaces are substantially coplanar with each other.

21. The laminate of claim 18, further comprising interconnect materials disposed over each of the exposed surfaces.

22. The laminate of claim 18, wherein the embedding material comprises an amalgam.

23. The laminate of claim 22, wherein the amalgam comprises a matrix metal, an alloying metal and a low CTE material.

24. The laminate of claim 22, wherein the amalgam is a low CTE amalgam with a CTE of about −5 ppm/° C. to about 5 ppm/° C.
